(19) United States
(12) Patent Application Publication
(10) Pub. No.: US 2018/0183455 A1
(43) Pub. Date: Jun. 28, 2018

(54) MULTICORE SUCCESSIVE APPROXIMATION REGISTER ANALOG TO DIGITAL CONVERTER

(71) Applicant: Avnera Corporation, Beaverton, OR (US)

(72) Inventors: Wai Lee, Portland, OR (US); Jianping Wen, Tigard, OR (US); Garry N. Link, Pacific City, OR (US); Jian Li, Portland, OR (US)

(21) Appl. No.: 15/849,220

(22) Filed: Dec. 20, 2017

Related U.S. Application Data
(60) Provisional application No. 62/438,936, filed on Dec. 23, 2016.
(60) Provisional application No. 62/438,917, filed on Dec. 23, 2016.

(51) Int. Cl. H03M 1/46; H03M 1/12; H03M 1/10

(52) U.S. Cl. CPC H03M 1/462; H03M 1/1019; H03M 1/1245; H03M 1/466

(57) ABSTRACT

The disclosure includes an analog to digital converter (ADC). The ADC includes a successive approximation register (SAR) unit including one or more capacitive networks. The capacitive networks take a sample of an analog signal. The SAR also includes a comparator to approximate digital values based on the analog signal sample via successive comparison. The ADC includes a preamplifier coupled to the SAR unit. The preamplifier amplifies the analog signal for application to the capacitive networks for sampling. The ADC also includes a rough buffer coupled to the SAR unit. The rough buffer pre-charges the capacitive networks of the SAR unit prior to application of the analog signal from the preamplifier.

### CROSS-REFERENCES TO RELATED APPLICATIONS

The present application claims benefit from U.S. Provisional Patent Application Ser. No. 62/438,917, filed Dec. 23, 2016, and entitled “Multicore Successive Approximation Register ADC,” and claims benefit from U.S. Provisional Patent Application Ser. No. 62/438,936, filed Dec. 23, 2016, and entitled “SAR ADC,” which are incorporated herein by reference as if reproduced in their entirety.

### BACKGROUND

Analog to Digital Converters (ADCs) are employed in many technological areas. For example, an ADC may be employed to convert sound entering a microphone or light entering a receiver into a digital signal that can be stored and processed by a digital computing system. The conversion of an analog signal to a digital signal involves mapping a first set of values to a smaller second set of values, also known as quantization. Such quantization involves some level of truncation and/or rounding, which results in quantization error. Further, other ADC circuitry may inject noise into the signal during operation. Such error and noise negatively impact the Signal to Noise Ratio (SNR) of the ADC. Further, ADCs may operate in low power environments, for example when employed in systems operating from a battery. ADC circuits designed to maintain a high SNR for high quality conversion may drain significant power. Accordingly, balancing power consumption and SNR may dictate ADC design choices. Design choices that decrease power consumption without significantly decreasing SNR, or vice versa, may be beneficial.

### BRIEF DESCRIPTION OF THE DRAWINGS

Aspects, features and advantages of embodiments of the present disclosure will become apparent from the following description of embodiments in reference to the appended drawings in which:

FIG. 1 is a schematic diagram of an example Successive Approximation Register (SAR) Analog to Digital Converter (ADC) architecture.

FIG. 2 is a schematic diagram of an example capacitive network for a SAR ADC.

FIG. 3 is a schematic diagram of an example SAR core network.

FIG. 4 is a schematic diagram of an example multi-core SAR network for use in a speaker.

FIG. 5 is a schematic diagram of an multi-core SAR network for use in Active Noise Cancellation (ANC).

FIG. 6 is a flowchart of an example method of operating a SAR core.

FIG. 7 is a schematic diagram of a network for calibrating a SAR ADC.

FIG. 8 is a flowchart of an example method of calibrating a SAR ADC.

FIG. 9 is a flowchart of an example method of generating digital values from a SAR ADC based on calibration results.

### DETAILED DESCRIPTION

Disclosed herein is a SAR ADC that employs low power while providing high SNR. The SAR ADC may employ multiple low power SAR cores operating in parallel to increase the sampling rate of the system without raising power requirements associated with employing a high sampling rate core. Further, various components are only employed for portions of the overall duty cycle of the ADC system. Such components may be powered down when not in use to further reduce power consumption. A SAR core employs a capacitive network to sample an incoming analog signal and a comparator to iteratively determine successive bits for each sampled value. A preamplifier is employed to increase the power of the incoming analog signal for sampling. A rough buffer is further employed to pre-charge the capacitive network, which decreases power requirements of the preamplifier. Accordingly, once the rough buffer pre-charges the capacitive network, the preamplifier may provide sufficient power to fine tune the amount of charge in the capacitive network to the proper value of the analog signal. The preamplifier and/or the rough buffer may be shared between multiple SAR cores. In addition, the SAR ADC experience leakage current during operation. Such leakage current creates signal distortion and is proportional to signal swing during the SAR process. Signal swing is greatest when determining a Most Significant Bit (MSB). As such, a dedicated MSB comparator is positioned outside of the SAR core, which reduces signal swing in the SAR core and hence reduces leakage current and distortion. Further, the MSB comparator may be shared between multiple cores. In addition, the SAR ADC may employ a wide range of capacitors in the capacitive network. The capacitance for the capacitive network may vary significantly due to imperfections in a real world manufacturing process. A calibration circuit is employed to determine an array of capacitor weights. Such capacitor weights reflect the actual capacitance of each capacitor in a particular network. The capacitor weights may then be applied to the results of the SAR process to provide an accurate digital value. The presence of a wide range of capacitors in each capacitive network places constraints on the calibration circuit. For example, a calibration circuit capable of measuring the charge of the largest capacitors in the network may employ significant power and microchip circuit area. Accordingly, the array is created by measuring the capacitance of the smaller capacitor until a signal range of the calibration circuit is reached. Capacitance of larger capacitors may then be measured by determining a difference between a capacitance of a specified capacitor and a capacitance of a smaller capacitor immediately preceding the specified capacitor. Such differences may be represented as a vector and added to the array. The array may then be employed to determine accurate signal values without requiring a large calibration circuit with high power requirements. These and other aspects discussed below reduce power requirements while providing a high SNR. The disclosed SAR ADC may be employed in a wide range of applications, such as audio processing, communication systems, and/or any other system that converts analog signals to digital signals. As a particular, the disclosed SAR ADC may be employed in BLUETOOTH speakers, for ANC functions in headphones, and for other audio processing systems.

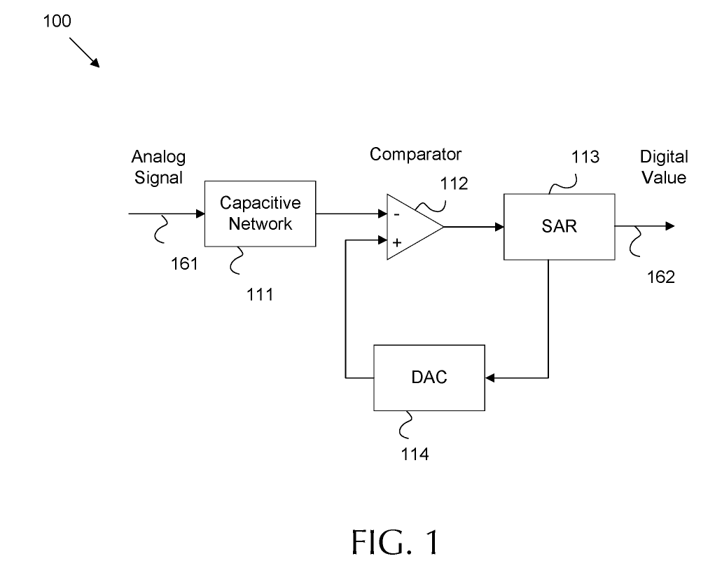

FIG. 1 is a schematic diagram of an example SAR ADC 100 architecture. The SAR ADC 100 includes a capacitive network 111, a comparator 112, a SAR 113, Digital to Analog Converter (DAC) 114 coupled as illustrated. The capacitive network 111 is coupled to an incoming analog signal 161. The capacitive network 111 includes a plurality of capacitors of varying levels of capacitance. The capacitors store charge from the analog signal 161 as a sample of the analog signal at a discrete instance in time. The SAR 113 may include a register for storing digital data as well as a circuit for providing known reference values. The DAC 114 is any device capable of converting a digital value to a corresponding analog signal value. The SAR 113 is configured to forward a known reference value (e.g. a one) via the DAC 114 to the comparator 112 for each bit of the sample. The comparator 112 is any electronic device capable of comparing two voltages and outputting an indication of which voltage is larger. The comparator 112 receives both voltage from the sample in the capacitive network 111 and the known value from the SAR 113 via the DAC 114. The comparator 112 then indicates which value is larger. The result of the comparison is stored in the SAR 113 as a bit of a corresponding digital value 162.

As such, the capacitive network 111 may include a capacitor/capacitor group for storing a portion of the analog signal for each bit desired in the digital value 162. The SAR ADC 100 may then iteratively test the electrical charge from each group of capacitors in the capacitive network 111 against the known value from the SAR 113 on a bit by bit basis. The results are stored in the SAR 113. Once all the desired bits have been tested, the resulting digital value 162 may be forwarded from the SAR ADC 100 for further use by coupled systems. The SAR ADC 100 provides accurate values so long as the capacitors in the capacitive network 111 include an expected capacitance. However, due to manufacturing variation, the capacitance of the capacitive network 111 may vary significantly from device to device. As such, various calibration techniques are discussed below to account for such variation. Such calibration allows the SAR ADC 100 to employ significantly reduced precision components, which in turn allows for the use of lower power components while maintaining accuracy and hence maintaining high SNR.

While an SAR ADC 100 may be implemented in many different fashions, it should be noted that the capacitive network 111 and the DAC 114 may be implemented in a common capacitor network. Further, the comparator 112 may contain one or more preamplifier stages that can be configured as a sampling Operational Transconductance Amplifier (OTA). Further, the comparator 112 can be configured as the only active component of the analog circuitry of SAR ADC 100. This supports creation of a low power and high precision design. While the reference accuracy of the DAC 114 may limit the resolution the SAR ADC 100 can achieve, digital calibration can be employed to calibrate the capacitive network 111 and mitigate such concerns.

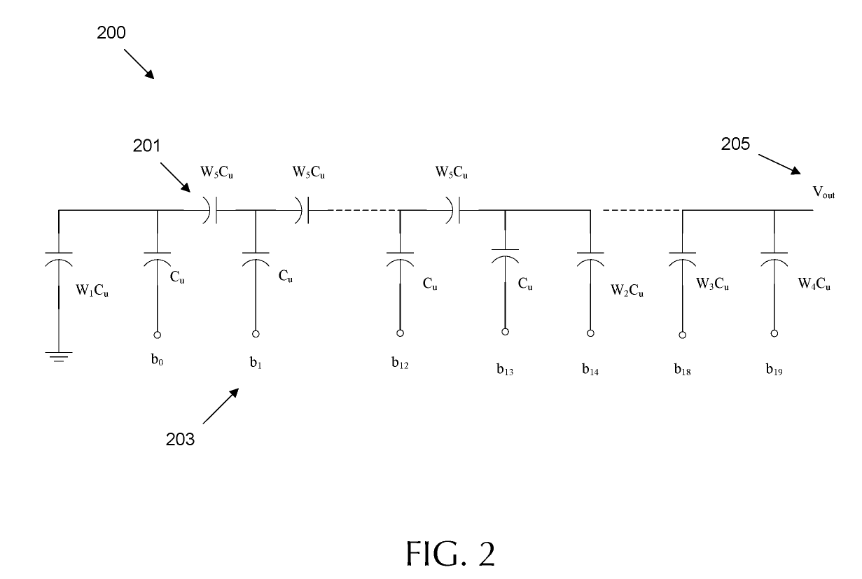

FIG. 2 is a schematic diagram of an example capacitive network 200 for a SAR ADC, such as a capacitive network 111 in a SAR ADC 100. The capacitive network 200 may include various capacitors 201, denoted as Cᵤ, with various ideal weights, denoted as W₁-W₅. For example, W₁-W₅ may be weighted as 1.56×, 2×, 24×, 44×, and 4×, respectively. As noted above, such weights may be ideal weights and may vary due to variations in real circuit manufacturing processes. The capacitive network 200 may include paths for storing various bit positions 203 for sampling. In the example shown, bit positions 203 are denoted b₀-b₁₉ to store a twenty bit value, with b0 indicating a MSB and b₁₉ indicating a Least Significant Bit (LSB), respectively. It should be noted that network 200 may be modified to store a sample of any resolution, and hence any number of bits. As such, bit positions 203 should be considered exemplary and non-limiting. During approximation, the charge stored in capacitors 201 is forwarded as an output voltage (Vₒᵤₜ) 205. Hence, Vₒᵤₜ 205 may be successively tested for each bit position 203 to determine a digital equivalent value for a sampled analog value received via electrical paths associated the bit positions 203. The bit positions 203 also may each be referred as a radix, where radix indicates a base and/or a number of unique digits used to represent a number, in this case a radix/base of two.

The radices among capacitor 201 bits of the network 200 may be arranged such that redundancy of each reference level is positive. It should be noted that the reference level is increasing error tolerant to Differential Non-Linearity (DNL) the larger the redundancy of each bit position 203. However, excessive redundancy may result in an inefficient network 200 that consumes extra power for the same conversion resolution. The tradeoff between redundancy and efficiency is compounded with internal parasitic effects of the network 200. In some cases, parasitic effects may cause a capacitive network 200 to exhibit negative redundancy for some bit positions 203, which may lead to conversion DNL. As network 200 is a passive network, a loading effect due to comparator input pair gate capacitance may be a concern. Such loading effect may reduce a full scale signal swing at comparator input. This may affect achievable SNR for a corresponding comparator noise performance. Further, the effective loading of a DAC network to sampling OTA should be minimized in order to achieve a target settling accuracy with a specified power consumption. However, a calibration circuit may mitigate such concerns.

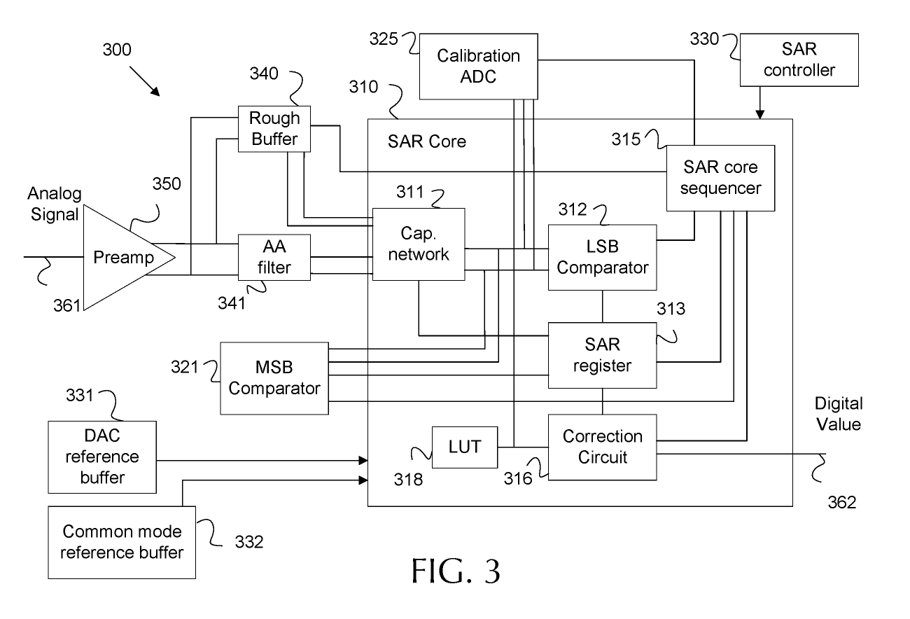

FIG. 3 is a schematic diagram of an example SAR core network 300, which may be employed to implement a SAR ADC architecture, such as SAR ADC 100 architecture. The SAR core network 300 may comprise at least one SAR core 310, but may also employ a plurality of SAR cores 310 in some examples as discussed further below. A group of one or more SAR cores 310 may be referred to herein as a SAR unit for clarity of discussion. The SAR core 310 receives and samples an analog signal 361 and outputs corresponding digital value(s) 362.

The SAR core network 300 includes a preamplifier 350 coupled to the SAR core 310. A preamplifier 350 is any electronic device that increases the power of a weak electrical signal to create a signal of sufficient strength for further processing. For example, the preamplifier 350 may amplify the analog signal 361 for application to a capacitive network 311 in the SAR core 310 for sampling. The capacitive network 311 may be substantially similar to capacitive network 111, capacitive network 200, DAC 114, or combinations thereof. Hence, the capacitive network 311 may take a sample of the analog signal 361, as amplified, and store the sample for approximation as a digital value 362. Hence, the capacitive network 311 may be referred to as a sample and hold circuit. The analog signal 361 may be forwarded via an anti-aliasing (AA) filter 341, which is any filter for mitigating signal distortion.

During operation, the SAR core 310 may take multiple samples. Hence, the capacitive network 311 may be discharged after a sample has been approximated, and then charged again when taking the next sample. Employing the preamplifier 350 to repeatedly charging the capacitive network 311 may place significant design constraints on the preamplifier 350. For example, quickly providing a sufficient and exact amount of charge to the capacitive network 311 may result in signal distortion, high power usage, and/or require a complex amplifier design. To mitigate such issues, the SAR core network 300 may include a rough buffer 340 to pre-charge the capacitive network 311 of the SAR core 310 prior to application of the analog signal 361 from the preamplifier 350. The rough buffer 340 may be any controllable voltage/current (e.g. charge) source. The rough buffer 340 pre-charges the capacitive network 311 to an approximate value (e.g. ninety percent) of the analog signal. The preamplifier 350 then provides sufficient power to adjust the charge in the capacitive network 311 up to the level of the analog signal 361. The amount of charge provided by the rough buffer 340 may be selected as an amount of charge that is lower than the amount of charge employed during a previous sample cycle. The SAR core 310 may spend a significant portion of an overall duty cycle approximating the digital value 362 from the sample. Hence the preamplifier 350 and the rough buffer 340 may be powered down when not in use to conserve power. Further, in embodiments that employ multiple SAR cores 310 in a SAR unit, the SAR cores 310 may share access to the preamplifier 350 and/or the rough buffer 340. Further, when many SAR cores 310 are employed (e.g. six) and a significant portion of the system duty cycle involves charging phases (e.g. about ⅙) the rough buffer may remained powered constantly, which may eliminate powering up/down transients.

Once the analog signal 361 has been sampled by the capacitive network 311, the SAR core 310 may employ comparators to approximate digital value(s) 362 based on the analog signal 361 sample via successive comparison. For example, each SAR core 310 may contain a LSB comparator 312 and may be coupled to a MSB comparator 321. The LSB comparator 312 and the MSB comparator 321 may be substantially similar to comparator 112. For example, the comparators 312 and 321 may each contain internal preamplifiers and a latch, which can be activated to make a comparison between inputs. The MSB comparator 321 determines a most significant bit for each digital value 362. The LSB comparator 312 then determines the remaining least significant bits. The MSB comparator 321 may be shared between multiple SAR cores 310 in some examples. The MSB comparator 321 is subject to more significant signal swings than the LSB comparator 312 because a switch of the first digit may cause twice the signal swing of a next digit (e.g. the most significant LSB). Signal swings may result in leakage current in attendance system circuits. Large signal swings may amplify such leakage currents, which may result in distortion and/or increased power usage. As such, the MSB comparator 321 selects the MSBs outside of the SAR core(s) 310 to mitigate signal swings and attendant leakage current. As with other shared components, the MSB comparator 321 may only be powered when determining MSBs for the SAR core(s) 310. The MSB comparator 321 may be powered down when not in use to conserve power.

The SAR core 310 may also include a SAR register 313, which may be substantially similar to SAR 113. The SAR core 310 may operate by accepting a sample of the analog signal at the capacitive network 311, which may also include a DAC. The most significant bit of the sample is forwarded from the capacitive network 311 to the MSB comparator 321 and compared to a reference value from the SAR register 313 and/or the DAC in the capacitive network 311. The result is stored in the SAR register 313. Such process is then repeated for each successive LSB at the LSB comparator 321, with the results stored in the SAR register 313 as an approximated digital value 362. The SAR core 310 may include a SAR core sequencer 315, which may be a control circuit configured to control the components of SAR core 310 in order to enact the sampling and successive approximation sequence. For example, the SAR core sequencer 315 may manage the duty cycle for the SAR core 310 by sending command pulses to the SAR core 310 components for each clock cycle according to a finite state machine. The SAR core 310 may be implemented as any form of control processor, for example as an Application Specific Integrated Circuit (ASIC), a Field Programmable Gate Array (FPGA), a Digital Signal Processor (DSP), a general purpose processor, and/or any other control circuit.

As noted above, capacitors may vary in capacitance due to variations in manufacturing processes. The SAR core network 300 includes a calibration ADC 325, a correction circuit 316, and a capacitor weight LookUp Table (LUT) 318 acting as a calibration circuit to correct for such variations. The calibration ADC 325 supports determination of an array of capacitor weight values for capacitors in the capacitive network 311. The calibration ADC 325 may be a delta sigma modulation ADC. The calibration ADC 325 may forward known reference values to the capacitive network 311. The SAR register 313 and the correction circuit 316 may then test the amount of charge on each capacitor in the capacitive network 311 against expected values. The correction circuit 316 may employ the test results to determine an array of capacitor weight values for the capacitors in the capacitive network 311. The capacitor array of capacitor weight values is stored in the capacitor weight LUT 318. The array of capacitor weight values may be determined during a calibration sequence. During SAR operation, the correction circuit 316 may generate digital signal values 362 based on the approximate digital values stored in the SAR register 313 and the capacitor weight values in the capacitor weight LUT 318. The capacitor weight LUT 318 may be any memory component, such as cache, Read Only Memory (RAM), Electrically Erasable Programmable Read-Only Memory (EEPROM), flash memory, etc. The correction circuit 316 may be configured from any logic circuit capable of determining capacitor weight values and determining digital values 362 based on the capacitor weight values and the results from the SAR register 313. For example, the correction circuit 316 may include an ASIC, a FPGA, a DSP, a general purpose processor, etc. It should also be noted that the calibration ADC 325 may be shared between multiple SAR cores 310. Further, the calibration ADC 325 may be powered down during the SAR process (e.g. when the calibration process is not active) to save power.

As noted above, the network 300 may include a SAR unit with a plurality of SAR cores 310. Hence, each of the SAR cores 310 include a capacitive network 311, an LSB comparator 312, a SAR register 313, a correction circuit 316, a LUT 318, and a SAR core sequencer 315. Such SAR cores 310 may be configured to operate in parallel by sampling the analog signal 361 at different points in the SAR core network 300 duty cycle. For example, a first SAR core 310 may take a first sample of the analog signal 361 and begin a SAR process on the first sample. A second SAR core 310 may then take a second sample of the analog signal 361 while the first SAR core 310 is processing the first sample. A third SAR core 310 may then take a third sample of the analog signal 361 while the first SAR core 310 and the second SAR core 310 are processing the first and second samples, respectively. The digital values 362 from the SAR cores 310 may then be interleaved into a digital signal. The SAR core network 300 also include a SAR controller 330 this process. The SAR controller 330 may be coupled to the SAR unit including the cores 310. The SAR controller 330 may initiate the SAR process on each core 310 in an offset manner by communicating with the SAR core sequencers 315. The SAR controller 330 may also manage interleaving the digital values 362 from the SAR cores 310 into a digital signal corresponding to the analog signal 361. The SAR controller 330 may include an ASIC, a FPGA, a DSP, a general purpose processor, etc.

The SAR core network 300 may also include a DAC reference buffer 331 and a common mode reference buffer 332. The DAC reference buffer 331 provides reference values to be employed by the comparators 312 and 321 when determining digital values 362 based on analog signal 361 samples. The DAC reference buffer 331 provides such reference values to both the DAC in the capacitive network 311 and the calibration ADC 325. Further, the SAR core network 300 may operate on differential signals. Hence, the common mode reference buffer 332 provides the other half of differential reference values. For example, the common mode reference buffer 332 may provide values at half the voltage of the DAC reference buffer 331. The DAC reference buffer 331 and the common mode reference buffer 332 may be implemented as circuits that provide specified charge based on values stored in a memory.

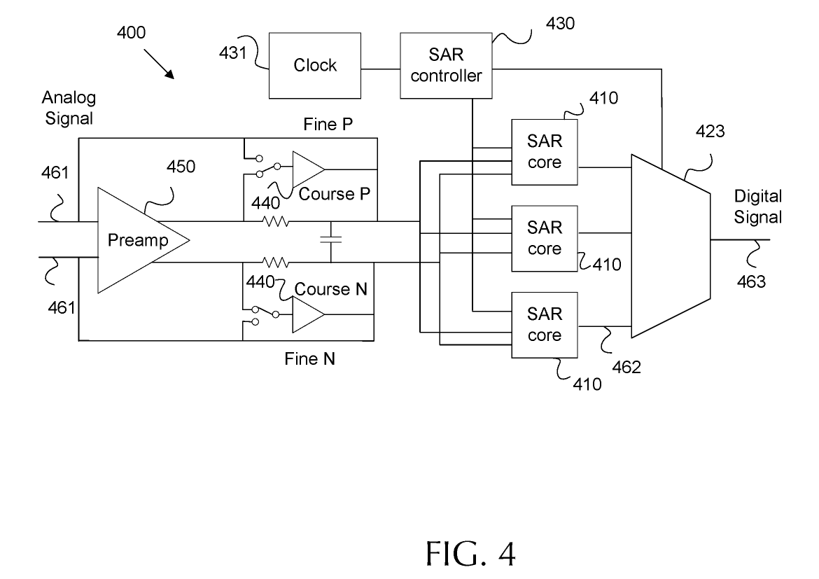

FIG. 4 is a schematic diagram of an example multi-core SAR network 400 for use as an ADC in a speaker. The multi-core SAR network 400 is a particular example of SAR core network 300 employing a capacitive network, such as capacitive network 200, according to a SAR ADC 100 architecture. As an example, the multi-core SAR network 400 may be employed for use in a BLUETOOTH speaker. The multi-core SAR network 400 employs a preamplifier 450 for receiving an analog signal 461, which may be substantially similar to preamplifier 350 and analog signal 361, respectively. The analog signal 461 is a differential signal and hence employs a positive line and a negative line. The multi-core SAR network 400 also includes a pair of rough buffers 440, which may be substantially similar to rough buffer 340. As shown, the switches are employs to allow the rough buffers 440 to provide a course positive charge and a course negative charge to capacitive networks in SAR cores 410. The rough buffers 440 can be switched off (and the preamplifier 450 switched on) to allow the preamplifier 450 to provide fine negative and fine positive charges to bring the capacitive network being charged up to proper charge for sampling.

The multi-core SAR network 400 includes a plurality of SAR cores 410, each of which may be substantially similar to SAR core 310. Each SAR core 410 may include a LSB comparator, such as LSB comparator 312, to determine a plurality of LSBs of an approximate digital value via successive comparison. The SAR cores 410 may also each include a register, such as SAR register 313 coupled to the LSB comparator. The register receives approximate digital values based on an analog signal 461 sample. The SAR cores 410 may share the preamplifier 450 and rough buffers 440 as discussed above. The multi-core SAR network 400 may also include a MSB comparator, such as MSB comparator 321. The MSB comparator may be coupled to, and shared between, the SAR cores 410. The MSB comparator may determine the MSBs of the approximate digital values.

As shown, the SAR cores 410 may be configured to operate in parallel. For example, each SAR core 410 may sample the analog signal 361 at different points in a duty cycle of the ADC. This allows the multi-core SAR network 400 to provide an overall sampling rate that is higher than employing a single SAR core 410. As three SAR cores 410 are depicted, the sampling rate is three times higher. However, any number of SAR cores 410 may be employed.

The multi-core SAR network 400 may also include a multiplexer (MUX) 423 controlled by a SAR controller 430. The SAR controller 430 may be substantially similar to SAR controller 330. The SAR controller 430 may be coupled to the SAR cores 410. The SAR controller 430 may operate the MUX 423 to interleave digital values (e.g. digital values 362) from the SAR cores 410 into a digital signal 463 corresponding to the analog signal 461 sampled by the SAR cores 410. The digital signal 463 may be a series of digital values corresponding to the analog signal 461. The SAR controller 430 may also operate according to a system clock 431, which may output clock edges used by the network 400 components to transition between states. The system clock 431 may be any clock suitable for such a purpose. For example, the system clock 431 may operate at about twelve megahertz (MHz), with the network employing a clock multiplier to operate at about twenty four MHz. Further, the SAR controller 430 may control calibration (e.g. initiate calibration, pause/restart ADC, power down components etc.) and other ADC functions for network 400 as discussed above.

The multi-core SAR network 400 may also include a calibration circuit, such as a calibration ADC 325 with corresponding correction circuits 316 and LUTs 318 in each SAR core 410. The SAR cores 410 employ capacitive networks and comparators. Hence, the SAR cores 410 share access to the calibration circuit, which is employed to generate an array of capacitor weight values for each SAR core 410. The SAR cores 410 may then use individualized capacitor weights to correct for variation in capacitance for each capacitive network in each SAR core 410.

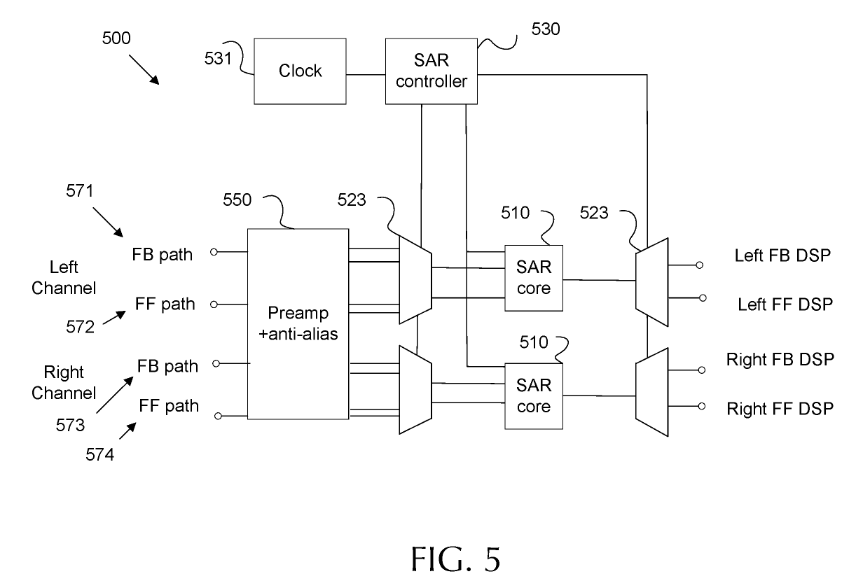

FIG. 5 is a schematic diagram of an multi-core SAR network 500 for use in ANC. The multi-core SAR network 500 is a particular example of SAR core network 300 employing a capacitive network, such as capacitive network 200, according to a SAR ADC 100 architecture. As an example, the multi-core SAR network 500 may be employed for use in a pair of headphones employing ANC. ANC is a technology for measuring ambient sound and introducing an anti-noise signal to cancel the measured ambient sound. The network 500 may employ both FeedForward (FF) and FeedBack (FB) systems. A FF system employs a microphone position on an outer portion of a headphone speaker (e.g. outside a headphone speaker cup and/or outside a user's ear canal). The FF system measures noise before such noise reaches the user's ear. The FF system then creates the anti-noise signal to cancel out such noise as the noise reaches the user. A FB system employs a microphone adjacent to a headphone speaker (e.g. inside a headphone speaker cup and/or inside a user's ear canal). The FB system measures the sound a user actually hears and then creates an anti-noise signal. The FF system may operate more quickly to prevent noise before such noise is heard, while the FB system may measure the results of the anti-noise signal and provide corrective action as desired.

Specifically, the network 500 may include a FB path 571 and a FF path 572 for a left channel as measured by FB and FF microphones, respectively, for a headphone for a user's left ear. The network 500 may also include a FB path 573 and a FF path 574 for a right channel as measured by FB and FF microphones, respectively, for a headphone for a user's right ear. The network 500 may include one or more preamplifiers 550 and antialiasing circuits, which are substantially similar to preamplifier 350 and AA filter 341, respectively. A dedicated preamplifier 550 may be employed for each path 571-574, a pre-amplifier may be shared between paths (e.g. a left channel preamplifier 550 and a right channel preamplifier 550), and/or a single pre-amplifier 550 may be shared for all paths 571-574. The network 500 also includes a plurality of SAR cores 510, which may each be substantially similar to SAR core 310. The SAR cores 510 may share a rough buffer and/or preamplifier 550. The SAR cores 510 may also share an MSB comparator and/or a correction circuit. As shown, a first SAR core 510 may employed for the left channel FB and FF paths 571-572, while a second SAR core 510 may be employed for the right channel FB and FF paths 573-574. The SAR cores 510 may convert analog signals from microphones in the headphones into digital signals for use by corresponding digital signal processors (DSPs). The DSPs may then generate the anti-noise signals based on the digital signals. It should be noted that a single SAR core 510 may be employed for all paths 571-574 or a SAR core 510 may be employed for each path 571-574 (e.g. four SAR cores 510) in some examples.

The network 500 may include a clock 531 and a SAR controller 530, which may be substantially similar to clock 431 and SAR controller 330 and/or 430, respectively. The SAR controller 530 may interleave the paths 571-574 to the SAR cores 510 and interleave corresponding digital values into digital signals for the DSP(s) by employing a network of MUXs 523 (and/or other switches) as shown. The SAR controller 530 may also control the sequencing of the of ADC conversion by the SAR cores 510. Further, the SAR controller 530 may control calibration and ADC functions for network 500 as discussed above.

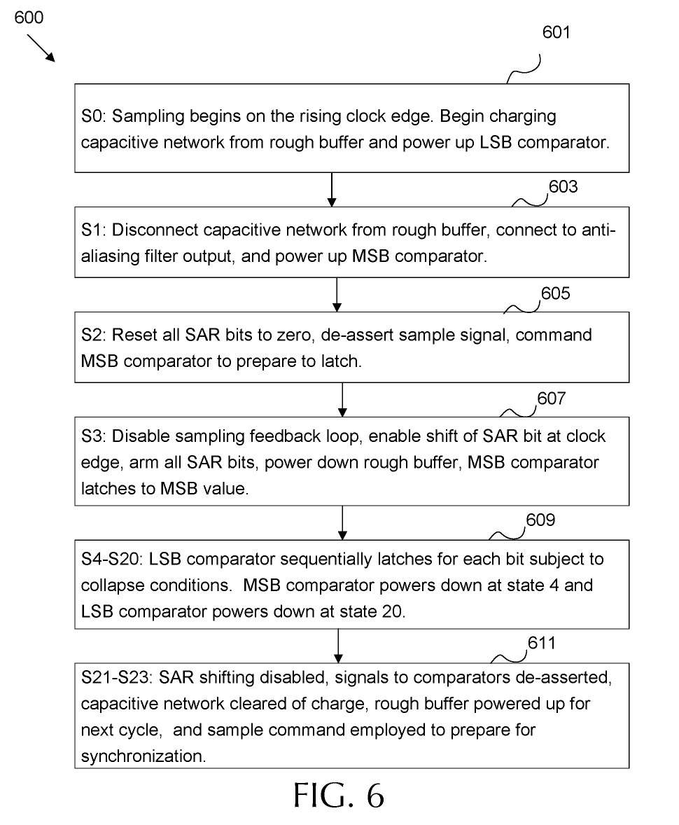

FIG. 6 is a flowchart of an example method 600 of operating a SAR core, such as a SAR core 310, 410, and/or 510, to convert an analog signal sample into a digital value. A SAR core may operate according to a finite state machine. Method 600 describes a finite state machine with twenty four states numbered from state zero (S0) to state twenty three (S23). When operating in a multi-core environment, method 600 may operate on each core in an offset manner. For example, a first core may enter S0 while a second core is entering state seven (S7) and while a third core is entering state fifteen (S15). The method 600 may operate repeatedly to continuously generate digital values based on incoming values.

At block 601, the method 600 enters SO, which begins the process of sampling the analog signal at the start of a rising clock edge. For example, a sample synchronization command may be forwarded by the SAR sequencer to any relevant switches to begin storing charge. It should be noted that a falling clock edge may employed to begin sampling in some examples. The bottom plates of the sampling capacitors in the capacitive network, which may be empty from the previous cycle, are connected to the rough buffer to begin charging up. The SAR sequencer may accomplish this by employing a sample rough command. Further, the LSB comparator may begin powering up for use in later states. The SAR sequencer may accomplish this by employing a power up comparator command.

At block 603, the method 600 enters state one (S1). By S1, the capacitive network is mostly charged, so the capacitive network is disconnected from the rough buffer and coupled to the output of the anti-aliasing filter. This allows the preamplifier to charge the capacitive network to the correct value for the sample of the analog signal. Further, the MSB comparator is powered up. The SAR sequencer may accomplish this by de-asserting a sample rough command and asserting a power up MSB comparator command, respectively.

At block 605, the method 600 enters state two (S2). The bits in the SAR register may be reset to zero to remove remaining data from a previous cycle. For example, the SAR sequencer may employ a clear command. Further, the SAR sequencer may de-assert a sample signal command to lock in the charge value in the capacitive network, and hence lock in the analog signal sample. The SAR sequencer may also command the MSB comparator to prepare to latch in order to compare an MSB value for the sampled signal, for example by employing a power up/latch command.

At block 607, the method 600 enters state three (S3). Once the system synchronizes on an internal clock signal (e.g. according to the sample synchronization command), the sampling feedback loop associated with the OTA in the MSB comparator is disabled. Further, the SAR sequencer may employ a shift command to enable shifting functionality at the SAR register. This allows the SAR register to shift to a next bit location at the next clock edge (e.g. after receiving a value). The clear command is de-asserted, which arms the SAR bits in the SAR register. Further, the rough buffer is powered down by de-asserting a power up rough buffer command from a previous cycle. In addition, the MSB comparator latches to a MSB value by comparing an MSB path in the capacitive network to a reference value. For example, the MSB value can be stored in the SAR register as −1 or +1 depending on whether the sample exceeds the reference value.

At block 609, the method 600 continues through states four through twenty (S4-S20). In these states, the LSB comparator sequentially latches a value for each bit, and such values are stored in the SAR register. Such bits may be stored as −1 or +1. Collapse conditions may also be employed. For example, a high bit followed by several sequential low bits (e.g. +1 −1 −1 −1) or a low bit followed by several high bits (e.g. −1 +1 +1 +1) may occur if the analog signal is almost zero (e.g. a very low volume). In such a case, the bits may be collapsed to zero. The collapsed zero bits may not be modified by the correction circuit, while the remaining −1 and +1 bits may be modified. This is because the zero bits may be assumed to include no useful information. It should be noted that the MSB comparator may be powered down at S4 to conserve power by de-asserting the power up MSB comparator command. Further, the LSB comparator may be powered down at state twenty (S20) to save power by de-asserting the power up comparator command. After the completion of S20, the approximate digital value is available in the SAR register for reading and correction by the correction circuit.

At block 611, the method 600 prepares to take another sample in the next cycle by proceeding through states twenty one through twenty three (S21-23). At S21, the shift command is de-asserted to disable SAR register shifting between bit positions. The power up latch command is also de-asserted to disable the comparator from synchronizing with the system clock. Further, a return to zero command is asserted at state twenty two (S22) to clear the sample charge in the capacitors in the capacitive network. At S23 the return to zero command is de-asserted. Further, a power up rough buffer command is asserted to prepare the rough buffer to begin pre-charging the capacitive network in the next cycle. Finally, the sample signal command is asserted to cause the system to switch power from the rough buffer to the capacitive network upon returning to S0. Method 600 may be repeated endlessly by a SAR core operating in SAR mode. It should be noted that modification of S0-S24 may be undertaken to reduce the number of states without departing from the scheme described herein. Further, method 600 may be paused when the SAR core is calibrated as discussed below and/or when powered off.

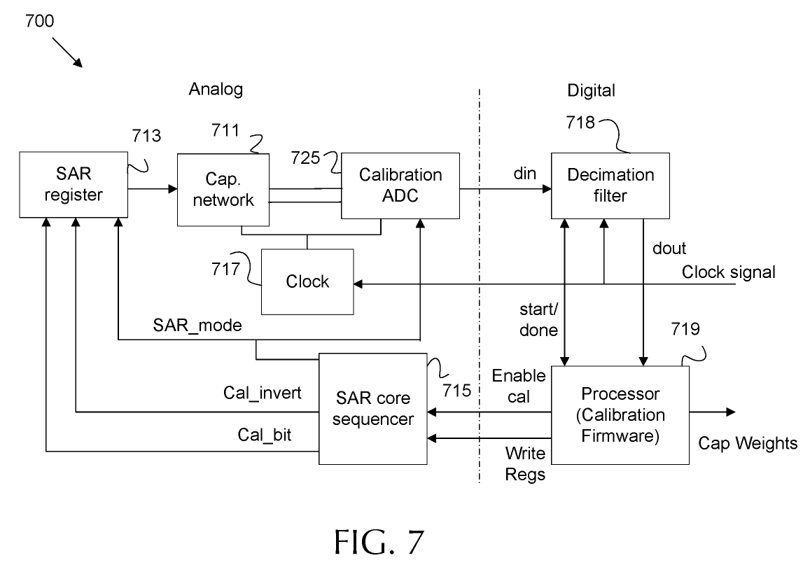

FIG. 7 is a schematic diagram of a network 700 for calibrating a SAR ADC. For example, network 700 may be employed to calibrate a correction circuit with an array of capacitor weight values for use by network 300, 400, and/or 500 in correcting approximate digital values. The network 700 is described in terms of the function of components when the SAR ADC process is paused and a calibration process is operational. The network 700 includes multiple components operating in an analog domain including a SAR register 713, a capacitive network 711, a calibration ADC 752, a clock 717, and a SAR core sequencer 715, which are substantially similar to the SAR register 313, the capacitive network 311, the calibration ADC 325, the clock 431/531, and the SAR core sequencer 315. The network 700 also includes components operating in a digital domain including a decimation filter 718 and a processor 719 operating calibration firmware. The decimation filter 718 may include any filter for downsampling (e.g. reducing the sampling rate of) a signal. The decimation filter is employed to match the sampling rate from the analog domain to a rate manageable by the processor 719. The processor 719 may be any processor with configurable logic, such as a DSP.

It should be noted that the calibration ADC 752 may contain a limited storage size and may be tuned to accurately measure the smallest capacitors in the capacitive network 711. For example, capacitance may be measured to an accuracy of twenty bits. The larger capacitors may require more bits to represent greater capacitance values when measured at the same resolution as the smaller capacitors. Hence, the calibration ADC 752 may be unable to directly measure the largest capacitors in the capacitive network 711 due to storage overflows. Such a limitation may be overcome by causing the calibration ADC 752 to measure the difference between a capacitor charge of a smaller measurable capacitor and a capacitor charge of a larger capacitor. The difference may then be employed to determine an actual capacitance value for the larger capacitor. The difference may be determined by inverting selected bits to determine the difference between capacitor charges. The difference may be stored in a vector as part of the capacitor weight value array.

The calibration firmware in the processor 719 may signal an enable calibration command to the SAR core sequencer 715 to initiate the calibration process. The processor 719 may also de-assert a start signal to the decimation filter to asynchronously clear a done signal from a previous measurement of a previous bit. The calibration firmware employs a write register command to the SAR core sequencer 715 to indicate which register to calibrate and which registers to invert when measuring a capacitor group for a specified bit. The calibration firmware may read the register to be calibrated and the registers to be inverted to verify the proper registers have been written to the SAR core sequencer 715. The calibration firmware then initiates a start signal to begin the calibration measurement for the specified bit. The SAR core sequencer 715 then asserts the calibration bit and the bits to be inverted, if any. The SAR core sequencer 715 also asserts a SAR mode command to the SAR register 713 and the calibration ADC 725 to begin calibration. The SAR register 713 then forwards specified reference charges toward the calibration ADC 725 via the capacitive network 711. The calibration ADC 725 determines the capacitance of the capacitor group associated with the calibration bit, in some cases based on the inverted bits. Such determination is made at clock edges provided by clock 717. The determined capacitance is then forwarded by the calibration ADC 725 to the processor 719 via the decimation filter 718. The decimation filter 718 may down sample the data from the calibration ADC 725 to make the data understandable by the processor 719. The processor 719 may employ the capacitance to determine a capacitor weight value for the specified bit for use in a SAR ADC process. Once the measurement is completed, the decimation filter 718 may assert a done signal. As noted above, each capacitance may be measured to an accuracy of twenty bits. Hence, the twenty most significant bits of capacitance for each measured capacitor group may be forwarded from the calibration ADC 725 to the processor 719. The network 700 may calibrate the LSB first, iteratively calibrate each successively larger bit, and calibrate the MSB last. An overall offset coefficient may be calculated with no bits selected and no bits inverted. The capacitance measured for a specified bit and the offset coefficient may be employed to determine the array of capacitor weight values. Once the capacitor weight values are determined, normalization may be employed on the array. The normalized array may then be employed during SAR ADC as discussed above.

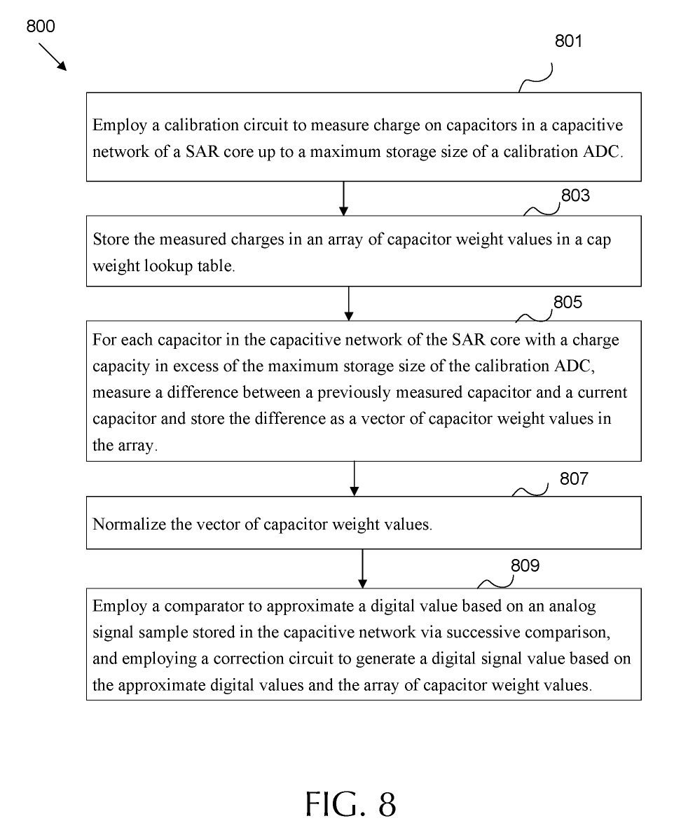

FIG. 8 is a flowchart of an example method 800 of calibrating a SAR ADC, for example by employing a network 700 in connection with network 300, 400, and/or 500. Method 800 may be implemented in a network employing one or more SAR cores, such as 310, 410, and/or 510. At block 801, a calibration circuit including a calibration ADC, such as calibration ADC 325 and/or 725, is employed to measure charge on capacitors in a capacitive network of the SAR core up to a threshold storage size of a calibration ADC. In a particular example, at a resolution sufficient to accurately measure the capacitors for a least significant bit 0, bits 0-9 may be measured and represented without exceeding a threshold storage size of a calibration ADC. At block 803, the measured charges may be stored as an array of capacitor weight values in a capacitor weight lookup table, such as capacitor weight LUT 318.

At block 805, capacitor weight values are determined for capacitors with a charge capacity that would cause an overflow if measured directly. In a particular example, capacitors for bits 10-17 may not be measured directly, where bit 17 is an MSB. For each capacitor in the capacitive network of the SAR core with a charge capacity in excess of the threshold storage size of the calibration ADC, a difference measured between a previously measured capacitor charge capacity and a current capacitor charge capacity. The results of the difference are then stored as part of a vector of capacitor weight values in the array. For example, a bit 13 may be accurately measured by measuring a difference between bit 13 and bit 12, the immediately preceding bit. The difference may be accomplished by causing the SAR core sequencer to invert the preceding bit(s) (e.g. bit 12) during measurement of a current bit (e.g. bit 13). At block 807, the array of capacitor weight values are normalized for ease of computation. For example, each measured capacitance weight value/vector may be divided by a total capacitance weight value for the array, which may result in all capacitor weight values adding up to a value of one. It should be noted that the threshold storage size may be set to the maximum storage capacity of the calibration ADC. However, the threshold may be lowered as desired, for example to exchange noise for calibration linearity.

Once the array has been normalized and stored in an LUT, the array may be employed to correct for variations in the capacitor network when operating the SAR ADC in SAR mode. At block 809, a comparator is employed to approximate a digital value based on an analog signal sample stored in the capacitive network via successive comparison. A correction circuit, such as correction circuit 316, may be employed to generate a digital signal value based on the approximate digital values and the array of capacitor weight values. As discussed above, the method 800 may operate on an ADC that employs a rough buffer to pre-charge the capacitive network of the SAR core prior to application of the analog signal from a preamplifier. The rough buffer and/or preamplifier may be shared between multiple SAR cores. Further, such SAR ADC may employ a dedicated MSB comparator to determine a MSB of the approximate digital value of the analog signal sampled by the capacitive network. The dedicated MSB comparator and may also be shared between SAR cores. In addition, the SAR ADC employ a SAR controller to interleave digital values from a plurality of SAR cores into a digital signal corresponding to the analog signal sampled by the capacitive network. It should be noted that the calibration may be shared between a plurality of SAR cores, and hence act as part of a calibration circuit in multiple SAR cores. As such, a calibration process may include performing method 800 on each SAR core in the SAR ADC.

The following table indicates example vector definitions of capacitor weight values for an example system including bits 0-17:

TABLE 1

| | | Inverted | | | Normalized |
|---|---|---|---|---|---|
| Bit | Vector bit | bit | Measured | Assembled Cap weight | Cap weight |
| — | 00_0000_0000_0000_0000 | 0000_0000 | Coeff. | | |
| 17 | 11_1011_0100_0000_0000 | 1101_1010 | C<17> | V<17> = C<17> + V<16> + | W<17> = |
| | | | | V<15> + V<13> + V<12> − Coeff. | V<17>/Vt |
| 16 | 01_1110_0010_0000_0000 | 0111_0001 | C<16> | V<16> = C<16> + V<15> + | W<16> = |
| | | | | V<14> + V<13> + V<9> − Coeff. | V<16>/Vt |
| 15 | 00_1111_0110_0000_0000 | 0011_1011 | C<15> | V<15> = C<15> + V<14> + | W<15> = |
| | | | | V<13> + V<12> + V<10> + | V<15>/Vt |
| | | | | V<9> − Coeff. | |
| 14 | 00_0111_0100_0000_0000 | 0001_1010 | C<14> | V<14> = C<14> + V<13> + | W<14> = |
| | | | | V<13> + V<10> − Coeff. | V<14>/Vt |
| 13 | 00_0011_1010_0000_0000 | 0000_1101 | C<13> | V<13> = C<13> + V<12> + | W<13> = |
| | | | | V<11> + V<9> − Coeff. | V<13>/Vt |
| 12 | 00_0001_1100_0000_0000 | 0000_0110 | C<12> | V<12> = C<12> + V<11> + | W<12> = |
| | | | | V<10> − Coeff. | V<12>/Vt |
| 11 | 00_0000_1110_0000_0000 | 0000_0011 | C<11> | V<11> = C<11> + V<10> + | W<11> = |
| | | | | V<9> − Coeff. | V<11>/Vt |
| 10 | 00_0000_0110_0000_0000 | 0000_0001 | C<10> | V<10> = C<10> + V<9> − Coeff. | W<10> = |
| | | | | | V<10>/Vt |
| 9 | 00_0000_0010_0000_0000 | 0000_0000 | C<9> | V<9> = C<9> − Coeff. | W<9> = |
| | | | | | V<9>Nt |
| 8 | 00_0000_0001_0000_0000 | 0000_0000 | C<8> | V<8> = C<8> − Coeff. | W<8> = |
| | | | | | <8>Nt |
| 7 | 00_0000_0000_1000_0000 | 0000_0000 | C<7> | V<7> = C<7> − Coeff. | W<7> = |
| | | | | | V<7>Nt |
| 6 | 00_0000_0000_0100_0000 | 0000_0000 | C<6> | V<6> = C<6> − Coeff. | W<6> = |
| | | | | | V<6>Nt |
| 5 | 00_0000_0000_0010_0000 | 0000_0000 | C<5> | V<5> = C<5> − Coeff. | W<5> = |
| | | | | | V<5>Nt |
| 4 | 00_0000_0000_0001_0000 | 0000_0000 | C<4> | V<4> = C<4> − Coeff. | W<4> = |
| | | | | | V<4>Nt |
| 3 | 00_0000_0000_0000_1000 | 0000_0000 | C<3> | V<3> = C<3> − Coeff. | W<3> = |
| | | | | | V<3>Nt |
| 2 | 00_0000_0000_0000_0100 | 0000_0000 | C<2> | V<2> = C<2> − Coeff. | W<2> = |
| | | | | | V<2>Nt |
| 1 | 00_0000_0000_0000_0010 | 0000_0000 | C<1> | V<l> = C<1> − Coeff. | W<l> = |
| | | | | | V<1>Nt |
| 0 | 00_0000_0000_0000_0001 | 0000_0000 | C<0> | V<0> = C<0> − Coeff. | W<0> = |
| | | | | | V<0>Nt |

where C<x> indicates a measured capacitance of bit x, V<x> indicates a vector describing the measured capacitance of bit x, W<x> indicates the normalized capacitor weight for bit x, and Vt is a sum of all vectors (e.g. V<0> through V<17>). It should be noted that, while the above method is discussed in terms of an eighteen bit system, any number of bits may be employed.

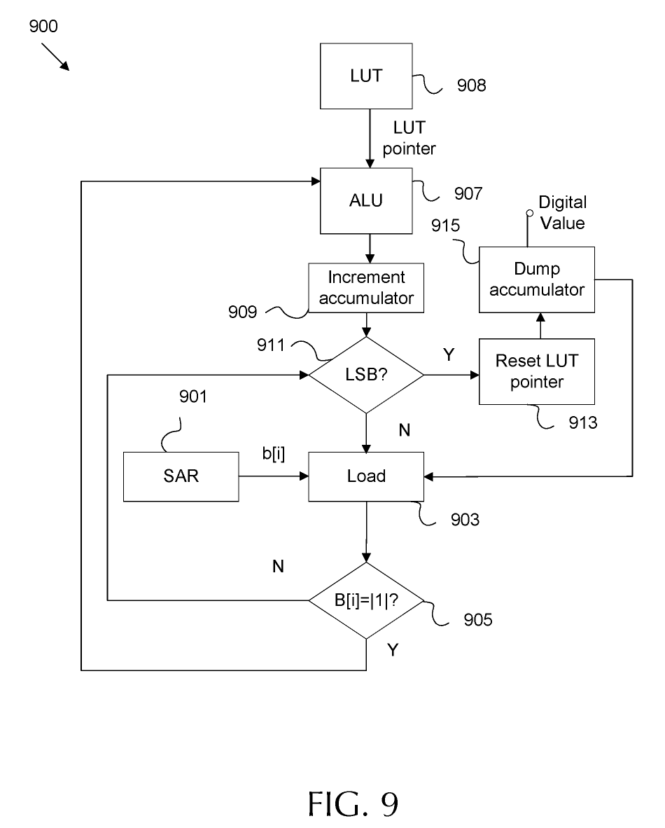

FIG. 9 is a flowchart of an example method 900 of generating digital values from a SAR ADC, such as network 300, 400, and/or 500, based on calibration results, for example from network 700 based on method 800. As a specific example, method 900 may be employed by a correction circuit, such as correction circuit 316, to generate digital signal values based on the approximate digital values and the capacitor weight values.

At block 901, a SAR register stores a plurality of approximate digital values determined from an analog sample and stored by bit position, denoted as b[i] where i indicates a current bit. The current bit is loaded into the correction circuit at block 903. The loaded bit may be a bit from an approximate digital value determined by the SAR core and stored in the SAR register. At block 905, the method 900 determines whether the loaded bit is a +1 or a −1, and hence contains data, or whether the loaded bit is 0, indicating the collapse condition has occurred (e.g. due to a very low amplitude signal such as near silence in audio processing). When the loaded bit is not |1| (e.g. 0), the method 900 proceeds to block 911 with the understanding that the loaded bit does not contain actual data. At block 911, the method 911 determines whether the loaded bit is the LSB, which indicates that no further processing is desired. If the loaded bit is not the LSB, then the method 900 returns to block 903 and loads a new bit from the current sample from the SAR register. If the loaded bit is the LSB, the method proceeds to block 913 and resets a LUT pointer, which sets the method 900 to correct a next sample. The method 900 then proceeds to block 915 and dumps an accumulator containing the corrected digital value, which forwards the corrected digital value (e.g. in this case collapsed data with no sound) to a DSP for further processing.

Returning to block 905, when the loaded bit is −1|, the method 900 proceeds to block 907 with the understanding that the loaded bit is actual data. At block 907, a processing circuit, such as an arithmetic logic unit (ALU), receives the bit loaded from the SAR register. The ALU of block 901 also receives a pointer into a capacitor weight LUT at block 908. By employing the LUT pointer, the ALU obtains the capacitor weight value and/or vector associated with the loaded bit. The ALU of block 901 then generates a corrected bit for the digital signal value based on the loaded approximate digital bit and the corresponding capacitor weight value/vector. At block 909, the corrected bit is stored in a location in an accumulator, and the accumulator is incremented to accept the next corrected bit. The method 900 the returns to block 911. If the corrected bit was not the LSB, the method 900 returns the block 903 and loads the next bit from the SAR register. If the corrected but was the LSB, the method 900 proceeds by resetting the LUT pointer for the next sample at block 913. The accumulator is also dumped at block 915 to forward the corrected digital signal value generated by the method 900 to the DSP for further processing.

Examples of the disclosure may operate on a particularly created hardware, on firmware, digital signal processors, or on a specially programmed general purpose computer including a processor operating according to programmed instructions. The terms “controller” or “processor” as used herein are intended to include microprocessors, microcomputers, Application Specific Integrated Circuits (ASICs), and dedicated hardware controllers. One or more aspects of the disclosure may be embodied in computer-usable data and computer-executable instructions (e.g. computer program products), such as in one or more program modules, executed by one or more processors (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as Random Access Memory (RAM), Read Only Memory (ROM), cache, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer readable media excludes signals per se and transitory forms of signal transmission. In addition, the functionality may be embodied in whole or in part in firmware or hardware equivalents such as integrated circuits, field programmable gate arrays (FPGA), and the like. Particular data structures may be used to more effectively implement one or more aspects of the disclosure, and such data structures are contemplated within the scope of computer executable instructions and computer-usable data described herein.

Aspects of the present disclosure operate with various modifications and in alternative forms. Specific aspects have been shown by way of example in the drawings and are described in detail herein below. However, it should be noted that the examples disclosed herein are presented for the purposes of clarity of discussion and are not intended to limit the scope of the general concepts disclosed to the specific examples described herein unless expressly limited. As such, the present disclosure is intended to cover all modifications, equivalents, and alternatives of the described aspects in light of the attached drawings and claims.

References in the specification to embodiment, aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when a particular feature, structure, or characteristic is described in connection with a particular aspect, such feature, structure, or characteristic can be employed in connection with another disclosed aspect whether or not such feature is explicitly described in conjunction with such other disclosed aspect.

### EXAMPLES

Illustrative examples of the technologies disclosed herein are provided below. An embodiment of the technologies may include any one or more, and any combination of, the examples described below.

Example 1 includes an analog to digital converter (ADC) comprising: a successive approximation register (SAR) unit including one or more capacitive networks to take a sample of an analog signal and one or more comparators to approximate digital values based on the analog signal sample via successive comparison; a preamplifier coupled to the SAR unit, the preamplifier to amplify the analog signal for application to the capacitive networks for sampling; and a rough buffer coupled to the SAR unit, the rough buffer to pre-charge the capacitive networks of the SAR unit prior to application of the analog signal from the preamplifier.

Example 2 includes the ADC of Example 1, wherein the SAR unit includes a plurality of SAR cores, each including at least one of the capacitive networks and at least one of the comparators, and wherein the SAR cores are configured to operate in parallel by sampling the analog signal at different points in an SAR unit duty cycle.

Example 3 includes the ADC of Example 2, wherein the SAR cores share access to the rough buffer.

Example 4 includes the ADC of Examples 2-3, wherein the SAR cores share access to the preamplifier.

Example 5 includes the ADC of Examples 2-4, further comprising a SAR controller coupled to the SAR unit, the SAR controller to interleave digital values from the SAR cores into a digital signal corresponding to the analog signal.

Example 6 includes the ADC of Examples 2-5, further comprising a most significant bit (MSB) comparator shared between the SAR cores, the MSB comparator to determine a most significant bit for each digital value.

Example 7 includes the ADC of Examples 1-6, further comprising: a calibration circuit to determine an array of capacitor weight values for capacitors in the capacitive networks; a cap weight lookup table for storing the capacitor weight values; and a correction circuit to generate digital signal values based on the approximate digital values and the capacitor weight values.

Example 8 includes the ADC of Examples 1-7, wherein the SAR unit includes a plurality of SAR cores, each including at least one of the capacitive networks and at least one of the comparators, and wherein the SAR cores share access to the calibration circuit.

Example 9 includes an analog to digital converter (ADC) comprising: a plurality of successive approximation register (SAR) cores, each SAR core including: a register to receive approximate digital values based on an analog signal sample; and a least significant bit (LSB) comparator coupled to the register to determine a plurality of LSBs of the approximate digital values via successive comparison; and a most significant bit (MSB) comparator coupled to, and shared between, the SAR cores, the MSB comparator to determine MSBs of the approximate digital values.

Example 10 includes the ADC of Example 9, wherein the MSB comparator selects the MSBs outside of the SAR cores to mitigate signal swings and attendant leakage current.

Example 11 includes the ADC of Examples 9-10, wherein the MSB comparator is only powered when determining MSBs for the SAR cores.

Example 12 includes the ADC of Examples 9-11, wherein the SAR cores are configured to operate in parallel by sampling an analog signal at different points in a duty cycle of the ADC.

Example 13 includes the ADC of Examples 9-12, further comprising a SAR controller coupled to the SAR cores, the SAR controller to interleave digital values from the SAR cores into a digital signal corresponding to an analog signal sampled by the SAR cores.

Example 14 includes the ADC of Examples 9-13, further comprising: a calibration circuit to determine an array of capacitor weight values for capacitors in sample and hold circuits in the SAR cores; a cap weight lookup table for storing the capacitor weight values; and a correction circuit to generate digital signal values based on the approximate digital values and the capacitor weight values.

Example 15 includes a method of calibrating a successive approximation register (SAR) based analog to digital converter (ADC), the method comprising: employing a calibration circuit to measure charge on capacitors in a capacitive network of a SAR core up to a threshold storage size of a calibration ADC; storing the measured charges as an array of capacitor weight values in a capacitor weight lookup table; and for each capacitor in the capacitive network of the SAR core with a charge capacity in excess of the threshold storage size of the calibration ADC, measuring a difference between a previously measured capacitor charge capacity and a current capacitor charge capacity as a vector and storing the vector as part of the array of capacitor weight values.

Example 16 includes the method of Example 15, further comprising normalizing the array of capacitor weight values.

Example 17 includes the method of Examples 15-16, further comprising employing a rough buffer to pre-charge the capacitive network of the SAR core prior to application of an analog signal from a preamplifier.

Example 18 includes the method of Examples 15-17, further comprising employing a dedicated most significant bit (MSB) comparator to determine a MSB of an approximate digital value of an analog signal sampled by the capacitive network.

Example 19 includes the method of Examples 15-18, further comprising: employing a comparator to approximate a digital value based on an analog signal sample stored in the capacitive network via successive comparison; and employing a correction circuit to generate a digital signal value based on the approximate digital values and the array of capacitor weight values.

Example 20 includes the method of Examples 15-19, further comprising employing a SAR controller to interleave digital values from a plurality of SAR cores into a digital signal corresponding to an analog signal sampled by the capacitive network.

The previously described examples of the disclosed subject matter have many advantages that were either described or would be apparent to a person of ordinary skill. Even so, all of these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

We claim:

1. An analog to digital converter (ADC) comprising:
a successive approximation register (SAR) unit including one or more capacitive networks to take a sample of an analog signal and one or more comparators to approximate digital values based on the analog signal sample via successive comparison;
a preamplifier coupled to the SAR unit, the preamplifier to amplify the analog signal for application to the capacitive networks for sampling; and
a rough buffer coupled to the SAR unit, the rough buffer to pre-charge the capacitive networks of the SAR unit prior to application of the analog signal from the preamplifier.

2. The ADC of claim 1, wherein the SAR unit includes a plurality of SAR cores, each including at least one of the capacitive networks and at least one of the comparators, and wherein the SAR cores are configured to operate in parallel by sampling the analog signal at different points in an SAR unit duty cycle.

3. The ADC of claim 2, wherein the SAR cores share access to the rough buffer.

4. The ADC of claim 2, wherein the SAR cores share access to the preamplifier.

5. The ADC of claim 2, further comprising a SAR controller coupled to the SAR unit, the SAR controller to interleave digital values from the SAR cores into a digital signal corresponding to the analog signal.

6. The ADC of claim 2, further comprising a most significant bit (MSB) comparator shared between the SAR cores, the MSB comparator to determine a most significant bit for each digital value.

7. The ADC of claim 1, further comprising:
a calibration circuit to determine an array of capacitor weight values for capacitors in the capacitive networks;
a cap weight lookup table for storing the capacitor weight values; and
a correction circuit to generate digital signal values based on the approximate digital values and the capacitor weight values.

8. The ADC of claim 7, wherein the SAR unit includes a plurality of SAR cores, each including at least one of the capacitive networks and at least one of the comparators, and wherein the SAR cores share access to the calibration circuit.

9. An analog to digital converter (ADC) comprising:
a plurality of successive approximation register (SAR) cores, each SAR core including:
a register to receive approximate digital values based on an analog signal sample; and
a least significant bit (LSB) comparator coupled to the register to determine a plurality of LSBs of the approximate digital values via successive comparison; and
a most significant bit (MSB) comparator coupled to, and shared between, the SAR cores, the MSB comparator to determine MSBs of the approximate digital values.

10. The ADC of claim 9, wherein the MSB comparator selects the MSBs outside of the SAR cores to mitigate signal swings and attendant leakage current.

11. The ADC of claim 9, wherein the MSB comparator is only powered when determining MSBs for the SAR cores.

12. The ADC of claim 9, wherein the SAR cores are configured to operate in parallel by sampling an analog signal at different points in a duty cycle of the ADC.

13. The ADC of claim 9, further comprising a SAR controller coupled to the SAR cores, the SAR controller to interleave digital values from the SAR cores into a digital signal corresponding to an analog signal sampled by the SAR cores.

14. The ADC of claim 9, further comprising:
a calibration circuit to determine an array of capacitor weight values for capacitors in sample and hold circuits in the SAR cores;
a cap weight lookup table for storing the capacitor weight values; and
a correction circuit to generate digital signal values based on the approximate digital values and the capacitor weight values.

15. A method of calibrating a successive approximation register (SAR) based analog to digital converter (ADC), the method comprising:
employing a calibration circuit to measure charge on capacitors in a capacitive network of a SAR core up to a threshold storage size of a calibration ADC;
storing the measured charges as an array of capacitor weight values in a capacitor weight lookup table; and
for each capacitor in the capacitive network of the SAR core with a charge capacity in excess of the threshold storage size of the calibration ADC, measuring a difference between a previously measured capacitor charge capacity and a current capacitor charge capacity as a vector and storing the vector as part of the array of capacitor weight values.

16. The method of claim 15, further comprising normalizing the array of capacitor weight values.

17. The method of claim 15, further comprising employing a rough buffer to pre-charge the capacitive network of the SAR core prior to application of an analog signal from a preamplifier.

18. The method of claim 15, further comprising employing a dedicated most significant bit (MSB) comparator to determine a MSB of an approximate digital value of an analog signal sampled by the capacitive network.

19. The method of claim 15, further comprising:
employing a comparator to approximate a digital value based on an analog signal sample stored in the capacitive network via successive comparison; and
employing a correction circuit to generate a digital signal value based on the approximate digital values and the array of capacitor weight values.

20. The method of claim 15, further comprising employing a SAR controller to interleave digital values from a plurality of SAR cores into a digital signal corresponding to an analog signal sampled by the capacitive network.
